(19) United States
(12) Patent Application Publication
(10) Pub. No.: US 2025/0204050 A1
(43) Pub. Date: Jun. 19, 2025

(54) DISPLAY DEVICE AND METHOD OF MANUFACTURING DISPLAY DEVICE

(71) Applicant: SAMSUNG DISPLAY CO., LTD., YONGIN-SI (KR)

(72) Inventor: Il Woo PARK, Yongin-si (KR)

(21) Appl. No.: 18/922,614

(22) Filed: Oct. 22, 2024

(30) Foreign Application Priority Data
Dec. 19, 2023 (KR) 10-2023-0186002

(51) Int. Cl. H01L 27/12; H01L 25/16; H10K 59/12; H10K 59/121; H10K 59/123

(52) U.S. Cl. CPC H10D 86/60; H10D 86/021; H10D 86/427; H10D 86/441; H01L 25/167; H10K 59/1201; H10K 59/1213; H10K 59/123

(57) ABSTRACT

Provided is a display device and a method of manufacturing a display device. The display device includes a pixel circuit layer including a base layer, a first layer which is disposed on the base layer and includes a first active layer, a second layer which is disposed on the first layer and includes a second active layer, and a third layer which is disposed on the second layer and includes an upper conductive layer and a via layer, and a light emitting element layer disposed on the pixel circuit layer, the light emitting element layer including a light emitting element. The first active layer and the second active layer include different semiconductor materials.

### CROSS-REFERENCE TO RELATED APPLICATION

This application claims priority under 35 U.S.C. § 119 to Korean Patent Application No. 10-2023-0186002, filed on Dec. 19, 2023 in the Korean Intellectual Property Office, the disclosure of which is incorporated by reference herein in its entirety.

### BACKGROUND

### 1. Technical Field

The present disclosure generally relates to a display device and a method of manufacturing a display device. More particularly, the present disclosure relates to a display device in which a failure of electrical structures included in the display device is reduced and a method of manufacturing the same.

### 2. Related Art

Research and development of display devices have been ongoing recently due to the growing interest in information displays.

A display device has a structure that is patterned with multiple layers. One such feature of the display device could be a contact structure that is electrically linked to the layers. To create the contact structure, one or multiple processes may be performed. As process steps are increased, process cost and difficulty may be increased.

### SUMMARY

Embodiments provide a display device and a method of manufacturing a display device, in which process steps can be simplified.

Embodiments also provide a display device and a method of manufacturing a display device, in which a risk that a conductive structure included in the display device will be damaged can be reduced.

Embodiments also provide a display device and a method of manufacturing a display device, in which a risk that a portion of a contact structure included in the display device will be disconnected can be reduced.

In accordance with an aspect of the present disclosure, there is provided a display device including: a pixel circuit layer including a base layer, a first layer which is disposed on the base layer and includes a first active layer, a second layer which is disposed on the first layer and includes a second active layer, and a third layer which is disposed on the second layer and includes an upper conductive layer; and a light emitting element layer disposed on the pixel circuit layer, the light emitting element layer including a plurality of light emitting elements, wherein the first active layer and the second active layer include different semiconductor materials, wherein each of the first layer and the second layer includes an interlayer insulating layer and an interlayer conductive layer, wherein the upper conductive layer includes a first upper conductive layer, a second upper conductive layer, and a third upper conductive layer, wherein the first active layer of the first layer is electrically connected to the first upper conductive layer through a first contact member penetrating the first and second layers, wherein the interlayer conductive layer of the first layer is electrically connected to the second upper conductive layer through a second contact member penetrating the first and second layers, wherein the second active layer of the second layer is electrically connected to the third upper conductive layer through a third contact member penetrating the second layer, and wherein the interlayer insulating layer of the first layer forms continuous side surfaces around the first contact member, the second contact member, and the third contact member.

The first active layer may include at least one of Low-Temperature Polycrystalline Silicon (LTPS), Hybrid Oxide Polycrystalline silicon (HOP), and Hybrid Oxide Low-Temperature Polycrystalline silicon (HOL).

The second active layer may include Indium Gallium Zinc Oxide (IGZO).

The interlayer conductive layer of the first layer may include a first conductive layer including aluminum (Al) and a second conductive layer which is disposed on the first conductive layer and includes titanium (Ti).

The interlayer conductive layer of the first layer may include a first interlayer conductive layer and a second interlayer conductive layer spaced apart from the first interlayer conductive layer. The first interlayer conductive layer may be disposed on a different layer from the second interlayer conductive layer. The second interlayer conductive layer may overlap the second active layer along a thickness direction.

The display device may further include: a display area and a non-display area; a lower auxiliary conductive layer on the base layer; and a via layer disposed on the interlayer insulating layer. A portion of the lower auxiliary conductive layer may overlap the first active layer in a thickness direction. A portion of the lower auxiliary conductive layer may be disposed in the display area, and another portion of the lower auxiliary conductive layer may be disposed in the non-display area.

The interlayer insulating layer may include first, second, third, fourth, and fifth interlayer insulating layers. Layers directly adjacent to each other among the first, second, third, fourth, and fifth interlayer insulating layers may include different materials.

The different materials may include silicon oxide (SiOₓ) and silicon nitride (SiNₓ).

In accordance with another aspect of the present disclosure, there is provided a method of manufacturing a display device, the method including: fabricating a pixel circuit layer; and fabricating a light emitting element layer on the pixel circuit layer, wherein the fabricating of the pixel circuit layer includes: forming, on a base layer, a plurality of layers including a first active layer, interlayer insulating layers, and an interlayer conductive layer; forming a first contact hole and a second contact hole, wherein the first contact hole is exposed to the first active layer, and the second contact hole is exposed to the interlayer conductive layer; performing an annealing process, wherein the performing of the annealing process includes forming an oxide layer on the first active layer; and removing the oxide layer.

The removing of the oxide layer may be accomplished by performing a cleaning process using Hydrogen Fluoride (HF).

The performing of the cleaning process may be accomplished by causing chemical reactions including an etchant preparation process, an oxide etching process, and a ramping process as follows:

HF+NH₃→NH₄F [Etchant preparation process]

6NH₄F+SiO₂→(NH₄)₂SiF₆(s)+2H₂O(g)+4NH₃(g) [Oxide etching process]

(NH₄)2SiF₆(s)→2NH₃(g)+SiF₄(g)+2HF(g). [Ramping process]

The interlayer insulating layers may include first, second, third, fourth, and fifth interlayer insulating layers directly adjacent to each other. Each of the first, second, third, fourth, and fifth interlayer insulating layers directly adjacent to each other may include silicon oxide (SiOₓ) and silicon nitride (SiNₓ). An etch selectivity of silicon oxide (SiOₓ) to silicon nitride (SiNₓ) with respect to an etchant provided in the cleaning process may be 0.9:1 to 1.5:1.

The first active layer may include at least one of Low-Temperature Polycrystalline Silicon (LTPS), Hybrid Oxide Polycrystalline silicon (HOP), and Hybrid Oxide Low-Temperature Polycrystalline silicon (HOL). The oxide layer may include silicon oxide (SiOₓ).

The interlayer conductive layer may include a first conductive layer and a second layer disposed on the first conductive layer. The first conductive layer may include aluminum (Al), and the second conductive layer may include titanium (Ti). The performing of the annealing process may be accomplished by a high-temperature heating technique using a furnace or Rapid Thermal Annealing (RTA) as a rapid annealing technique.

The plurality of layers may further include a second active layer including a semiconductor material different from a semiconductor material of the first active layer. The method may further include forming a third contact hole exposed to the second active layer.

The second active layer may include IGZO. No additional annealing process may be performed after the forming of the third contact hole.

The method may further include forming a plurality of contact members. The forming of the plurality of contact members may be accomplished by patterning a plurality of upper conductive layers. The upper conductive layer may include a first upper conductive layer, a second upper conductive layer, a third upper conductive layer, and an edge upper conductive layer. The patterning of the upper conductive layer may include: forming a first contact member electrically connecting the first upper conductive layer to the first active layer; forming a second contact member electrically connecting the second upper conductive layer to the interlayer conductive layer; forming a third contact member electrically connecting the third upper conductive layer to the second active layer, and forming an edge contact member electrically connecting the edge upper conductive layer to a lower auxiliary conductive layer.

The first contact hole and the second contact hole may be formed through an etching process using the same etch mask.

The first upper conductive layer, the second upper conductive layer, and the third upper conductive layer may be disposed in a display area, and the edge upper conductive layer may be disposed in a non-display area.

In accordance with another aspect of the present disclosure, there is provided a method of manufacturing a pixel circuit layer, the method including: forming a plurality of layers on a base layer, wherein the plurality of layer includes a first active layer, a second active layer, an interlayer insulating layer, and an interlayer conductive layer; forming a first contact hole and a second contact hole, wherein the first contact hole is exposed to the first active layer, and the second contact hole is exposed to the interlayer conductive layer; performing an annealing process, wherein the performing of the annealing process includes forming an oxide layer on the first active layer; removing the oxide layer, wherein the removing of the oxide layer is accomplished by performing a cleaning process using Hydrogen Fluoride (HF), forming a third contact hole, wherein the third contact hole is exposed to the second active layer, and forming a plurality of contact members including a first contact member, a second contact member, and a third contact member, wherein the forming of the plurality of contact members is accomplished by patterning a plurality of upper conductive layers, wherein the upper conductive layer includes a first upper conductive layer, a second upper conductive layer, and a third upper conductive layer, and wherein the first active layer is electrically connected to the first upper conductive layer through the first contact member, wherein the interlayer conductive layer is electrically connected to the second upper conductive layer through the second contact member, wherein the second active layer is electrically connected to the third upper conductive layer through the third contact member, and wherein the interlayer insulating layer forms continuous side surfaces around the first contact member, the second contact member, and the third contact member.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the present disclosure.

FIG. 2 is a schematic cross-sectional view a display device in accordance with an embodiment of the present disclosure.

FIG. 3 is a schematic cross-sectional view illustrating a display device including a pixel circuit layer in accordance with an embodiment of the present disclosure.

FIG. 4 is a schematic enlarged view of area EA1 shown in FIG. 3.

FIG. 5 is a schematic flowchart illustrating a method of manufacturing the display device in accordance with an embodiment of the present disclosure.

FIG. 6 is a schematic flowchart illustrating a step of manufacturing a pixel circuit layer in accordance with an embodiment of the present disclosure.

FIGS. 7 to 15 are schematic sectional views illustrating a method of manufacturing the display device in accordance with an embodiment of the present disclosure.

### DETAILED DESCRIPTION

The present disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The present disclosure generally relates to a display device. Hereinafter, a display device and a method of manufacturing a display device in accordance with an embodiment of the present disclosure will be described with reference to the accompanying drawings.

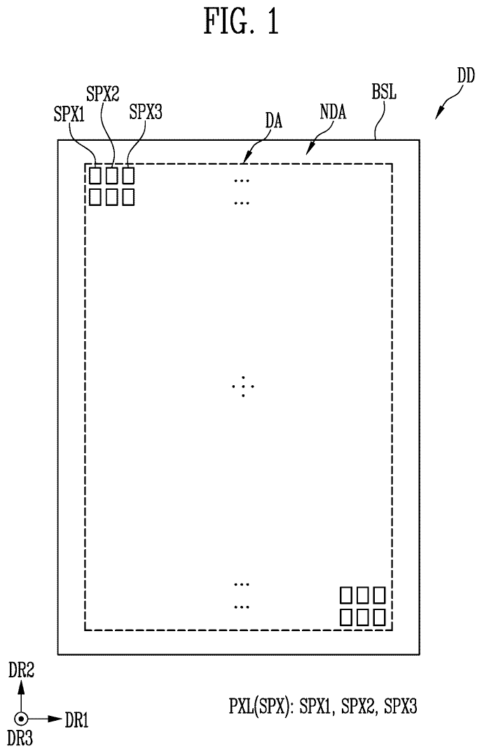

FIG. 1 is a schematic plan view illustrating a display device in accordance with an embodiment of the present disclosure.

Referring to FIG. 1, the display device DD includes a base layer BSL and a plurality of pixels PXL which are disposed on the base layer BSL. Although not shown in the drawing, the display device DD may further include a plurality of driving circuits (e.g., a scan driver and a data driver) for driving the pixels PXL, connecting lines, and pads.

The display device DD (or the base layer BSL) includes a display area DA and a non-display area NDA. The non-display area NDA may mean an area except the display area DA. The non-display area NDA may surround at least a portion of the display area DA. In this example, as depicted in FIG. 1, the non-display area NDA completely surround the display area DA. Furthermore, the display device DD may have a rectangular shape. However, in another example, the display device DD may have a triangular, circular, or any polygonal shapes.

The base layer BSL may provide a base surface to the display device DD. The base layer BSL may be a rigid or flexible substrate or film. For example, the base layer BSL may include a glass material. Alternatively, the base layer BSL may include a silicon material. More alternatively, the base layer BSL may include polyimide. However, the present disclosure is not limited thereto.

The display area DA may mean an area in which the plurality of pixels PXL are disposed. The non-display area NDA may mean an area in which the plurality of pixels PXL are not disposed. The driving circuit, the connecting lines, and the pads, which are connected to the plurality of pixels PXL of the display area DA, may be disposed around the non-display area NDA.

In accordance with an embodiment, the plurality of pixels PXL (or sub-pixels SPX) may be arranged according to a stripe arrangement structure, a PENTILE™ arrangement structure, or the like. However, the present disclosure is not limited thereto, and various embodiments may be applied in the present disclosure.

In accordance with an embodiment, the plurality of pixel PXL (or sub-pixels SPX) includes a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit which may emit lights of various colors such as red, blue, and green.

Each of the first sub-pixel SPX1, the second sub-pixel SPX2, and the third sub-pixel SPX3 may emit light of a color.

For example, the first sub-pixel SPX1 may emit light of red (e.g., a first color), the second sub-pixel SPX2 may emit light of green (e.g., a second color), and the third sub-pixel SPX3 may emit light of blue (e.g., a third color). The first sub-pixel SPX1 which emits the red light may provide light in a wavelength band of around 600 nm to 750 nm. The second sub-pixel SPX2 which emits the green light may provide light in a wavelength band of around 480 nm to 560 nm. The third sub-pixel SPX3 which emits the blue light may provide light in a wavelength band of around 370 nm to 460 nm.

In accordance with an embodiment, a number of second sub-pixels SPX2 may be greater than a number of first sub-pixels SPX1 and a number of third sub-pixels SPX3. However, the color, kind, and/or number of first, second, and third sub-pixels SPX1, SPX2, and SPX3 constituting each pixel unit are not limited to a specific example. In another example, a number of second sub-pixels SPX2 may be less than a number of first sub-pixels SPX1 and a number of third sub-pixels SPX3.

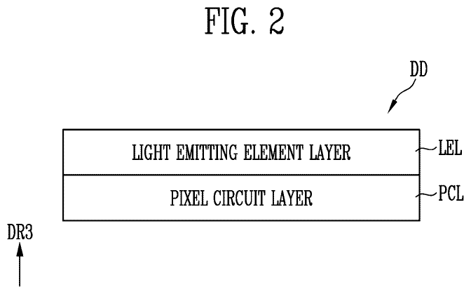

FIG. 2 is a schematic cross-sectional view a display device in accordance with an embodiment of the present disclosure.

Referring to FIG. 2, the display device DD may include a pixel circuit layer PCL and a light emitting element layer LEL disposed on the pixel circuit layer PCL.

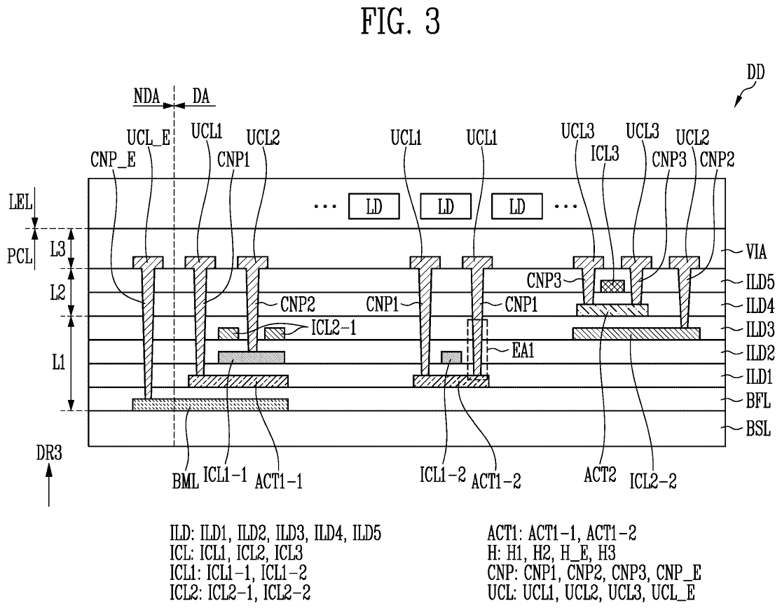

The pixel circuit layer PCL may include a base layer BSL (see FIG. 3). The pixel circuit layer PCL may be a layer including a pixel circuit. The pixel circuit layer PCL may be a backplane layer. The pixel circuit may be formed on the base layer BSL configured to drive a light emitting element LD (see FIG. 3). The pixel circuit layer PCL may include a plurality of conductive layers and insulating layers. The conductive layers may form the pixel circuit. The pixel circuit may include a plurality of circuit elements. The circuit elements may include a driving transistor and additional transistors and capacitors.

The light emitting element layer LEL may be disposed on a top of the pixel circuit layer PCL. Although not shown in FIG. 2, the light emitting element layer LEL may include the light emitting element LD. The light emitting element LD may be electrically connected to the pixel circuit. In some embodiments, the light emitting element LD may include an Organic Light Emitting Diode (OLED) including an organic material. Alternatively, in some embodiments, the light emitting element may include an inorganic light emitting diode including an inorganic material. However, the present disclosure is not limited thereto.

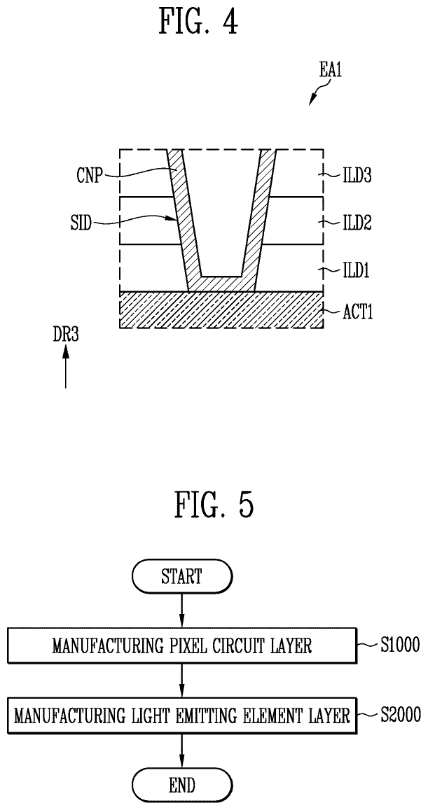

Hereinafter, the pixel circuit layer PCL will be described in more detail with reference to FIGS. 3 and 4.

FIG. 3 is a schematic cross-sectional view illustrating a display device including a pixel circuit layer in accordance with an embodiment of the present disclosure. FIG. 4 is a schematic enlarged view of area EA1 as shown in FIG. 3.

Referring to FIG. 3, the pixel circuit layer PCL includes the base layer BSL and a plurality of layers disposed on the base layer BSL. A plurality of contact members CNP penetrating at least a portion of the plurality of layers disposed on the base layer BSL is defined in pixel circuit layer PCL.

In some embodiments, the pixel circuit layer PCL may include a first layer L1, a second layer L2, and a third layer L3. The contact member CNP may include first, second and third contact members CNP1, CNP2, CNP3 and an edge contact member CNP_E. The first, second and third contact members CNP1, CNP2, CNP3 may be disposed in the display area DA, but the edge contact member CNP_E may be disposed in the non-display are NDA.

The first layer L1 may be disposed on the base layer BSL. The first layer L1 may be interposed between the base layer BSL and the second layer L2. The first layer L1 may correspond to layers including a first type semiconductor material. For example, the first layer L1 may include a first active layer ACT1.

The second layer L2 may be disposed on the first layer L1. The second layer L2 may be interposed between the first layer L1 and the third layer L3. The second layer L2 may correspond to layers including a second type semiconductor material which is different from the first type semiconductor material. For example, the second layer L2 may include a second active layer ACT2. The second active layer ACT2 may include an oxide semiconductor. In another example, the second active layer ACT2 may include Indium Gallium Zinc Oxide (IGZO).

The third layer L3 may be disposed on the second layer L2. The third layer L3 may be interposed between the second layer L2 and the light emitting element layer LEL. The third layer L3 may include a source electrode and/or a drain electrode, electrically connected to the first active layer ACT1. Furthermore, the third layer L3 may include a source electrode and/or a drain electrode, electrically connected to the second active layer ACT2. For example, the third layer L3 may include an upper conductive layer UCL, and the third layer L3 may be a layer disposed below the light emitting element layer LEL and include a via layer VIA.

In some embodiments, the first layer L1 and the second layer L2 may include an interlayer conductive layer ICL and an interlayer insulating layer ILD. The interlayer conductive layer ICL may include first, second, and third interlayer conductive layers ICL1, ICL2, ILC3. The interlayer insulating layer ILD may include first, second, third, fourth, and fifth interlayer insulating layers ILD1, ILD2, ILD3, ILD4, and ILD5.

For example, the first layer L1 may include a lower auxiliary conductive layer BML, a buffer layer BFL, and the first active layer ACT1. The lower auxiliary conductive layer BML may be disposed on the base layer BSL, and the first active layer ACT1 may be disposed on the lower auxiliary conductive layer BML and the buffer layer BFL. The first layer L1 may further include first and second interlayer conductive layers ICL1 and ICL2 and the first to third interlayer insulating layers ILD1, ILD2, ILD3.

For example, the second layer L2 may include the second active layer ACT2, and may further include the third interlayer conductive layer ICL3 and the fourth and fifth interlayer insulating layers ILD4 and ILD5.

In some embodiments, a pixel circuit of the pixel circuit layer PCL may be formed as at least a portion of each of the first and second active layers ACT1 and ACT2, the lower auxiliary conductive layer BML, the interlayer conductive layer ICL, the interlayer insulating layer ILD, and the upper conductive layer UCL is patterned in a structure in which the first and second active layers ACT1 and ACT2, the lower auxiliary conductive layer BML, the interlayer conductive layer ICL, the interlayer insulating layer ILD, and the upper conductive layer UCL are stacked.

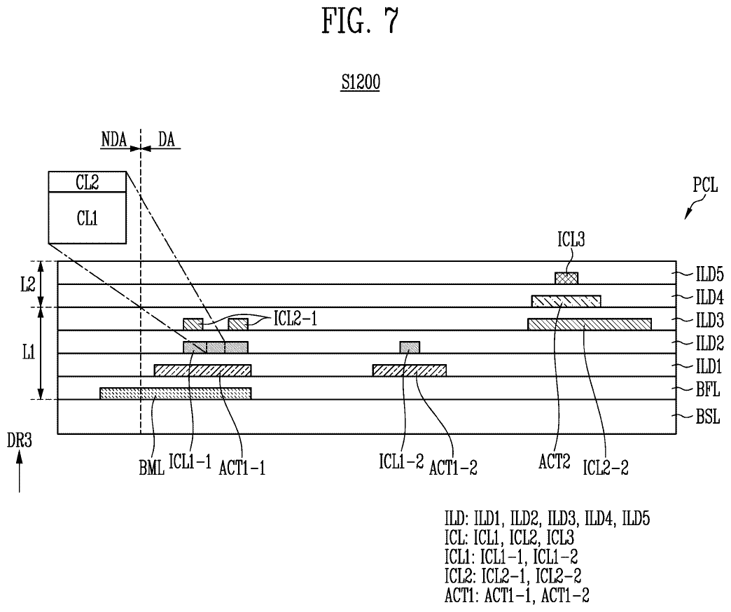

Each of the lower auxiliary conductive layer BML, the interlayer conductive layer ICL, and the upper conductive layer UCL may include one or more conductive layers. For example, the lower auxiliary conductive layer BML, the interlayer conductive layer ICL, and the upper conductive layer UCL may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). In some embodiments, the first and second interlayer conductive layers ICL1 and ICL2 may include a structure in which a second conductive layer CL2 (see FIG. 7) including titanium (Ti) is disposed on a first conductive layer CL1 (see FIG. 7) including aluminum (Al). However, the present disclosure is not necessarily limited to the above-described example.

In some embodiments, the upper conductive layer UCL may include first to third upper conductive layers UCL1, UCL2, UCL3, and may further include an edge upper conductive layer UCL_E. Although FIG. 3 illustrates the first to third upper conductive layers UCL1, UCL2, UCL3 are disposed in the same layer, the present disclosure is not limited thereto. For example, the first to third upper conductive layers UCL1, UCL2, UCL3 may be disposed in different layers within the third layer L3. For example, the third layer L3 may include a plurality of conductive layers disposed in different layers, and each of the first to third upper conductive layers UCL1, UCL2, UCL3 may be disposed in different layers. In this case, each of the first to third upper conductive layers UCL1, UCL2, UCL3 may be disposed the different layers. In another case, two of the upper conductive layers UCL may be disposed on the same layer, and one of the upper conductive layers UCL may be disposed on the different layer. For example, the first upper conductive layer UCL1 may be disposed on the same layer as the second conductive layer UCL2 or the third conductive layer UCL3. In another example, the first conductive layer UCL1 may be disposed on the same layer as the second conductive layer UCL2, but may be disposed on the different layer from the third conductive layer UCL3.

A buffer layer BFL may be interposed between the base layer BSL and the interlayer insulating layer ILD to cover the lower auxiliary electrode layer BML. The interlayer insulating layer ILD may be disposed between the above-described conductive layers. In some embodiments, the buffer layer BFL and the interlayer insulating layer ILD may include an inorganic material. For example, the inorganic material may include at least one selected from the group consisting of silicon nitride (SiNₓ), silicon oxide (SiOₓ), silicon oxynitride (SiOₓN_{y}), and aluminum oxide (AlₓO_{y}). However, the present disclosure is not limited to the above-described example.

In some embodiments, two of the adjacent layers among the interlayer insulating layers ILD may include different materials. For example, two interlayer insulating layers ILD among the first to fifth interlayer insulating layers ILD1 to ILD5, which directly contact each other may include different materials. The different materials may include silicon oxide (SiOₓ) and silicon nitride (SiNₓ). For example, the buffer layer BFL may include a structure in which silicon oxide (SiOₓ) and silicon nitride (SiNₓ) are sequentially disposed. The first interlayer insulating layer ILD1 may include silicon oxide (SiOₓ). The second interlayer insulating layer ILD2 may include silicon nitride (SiNₓ). The third interlayer insulating layer ILD3 may include a structure in which silicon oxide (SiOₓ) and silicon nitride (SiNₓ) are sequentially disposed. The fourth interlayer insulating layer ILD4 may include silicon oxide (SiOₓ). The fifth interlayer insulating layer ILD5 may include a structure in which silicon oxide (SiOₓ) and silicon nitride (SiNₓ) are sequentially disposed.

The via layer VIA may be disposed on the fifth interlayer insulating layer ILD5 to cover the upper conductive layer UCL. The via layer VIA may be a planarization layer. The via layer VIA may include an organic material. For example, the organic material may include at least one selected from the group consisting of acrylic resin, epoxy resin, phenolic resin, polyamide resin, polyimide resin, unsaturated polyester resin, poly-phenylene ether resin, poly-phenylene sulfide resin, and benzocyclobutene (BCB). However, the present disclosure is not limited to the above-described example.

The buffer layer BFL may prevent an impurity from being diffused into the first active layer ACT1 and the second active layer ACT2 or prevent moisture from infiltrating into the first active layer ACT1 and the second active layer ACT2. The buffer layer BFL may be disposed throughout a display area DA and the non-display area NDA.

The lower auxiliary conductive layer BML may be interposed between the base layer BSL and the buffer layer BFL. For example, the lower auxiliary conductive layer BML may be covered by the buffer layer BFL. The lower auxiliary conductive layer BML may overlap the first active layer ACT1 in a third direction (i.e., a thickness direction). A portion of the lower auxiliary conductive layer BML may be disposed in the non-display area NDA, and the other portion of the lower auxiliary conductive layer BML may be disposed in the display area DA. A portion of the lower auxiliary conductive layer BML which is disposed in the non-display area (NDA) may be electrically connected to the edge upper conductive layer UCL_E through the edge contact member CNP_E penetrating the first to fifth interlayer insulating layers ILD1 to ILD5 and the buffer layer BFL.

The first active layer ACT1 may be interposed between the buffer layer BFL and the first interlayer insulating layer ILD1. The first active layer ACT1 may be covered by the first interlayer insulating layer ILD1. The first active layer may be disposed in the display area DA. The first active layer ACT1 may form at least a portion of a circuit element (e.g., a semiconductor portion such as a driving transistor or a switching transistor) included in the pixel circuit configured to drive light emitting elements LD.

In some embodiments, the first active layer ACT1 may include a poly-silicon material. The first active layer ACT1 may include at least one of Low-Temperature Polycrystalline Silicon (LTPS), Hybrid Oxide Polycrystalline silicon (HOP), and Hybrid Oxide Low-Temperature Polycrystalline silicon (HOL).

The first active layer ACT1 may be electrically connected to the first upper conductive layer UCL1 through the first contact member CNP1 penetrating the first to fifth interlayer insulating layers ILD1 to ILD5. The first contact member CNP1 may be formed with the first upper conductive layer UCL1 through the same process, and include the same material as the first upper conductive layer UCL1. The first contact member CNP1 may be a structure electrically connecting the first active layer ACT1 to a conductive layer (e.g., the first upper conductive layer UCL1) of the third layer L3.

In some embodiments, the first active layer ACT1 may include a (1-1)th active layer ACT1-1 and a (1-2)th active layer ACT1-2. The (1-1)th active layer ACT1-1 and the (1-2)th active layer ACT1-2 may be spaced apart from each other. However the (1-1)th active layer ACT1-1 and the (1-2)th active layer ACT1-2 may be formed through the same process. In this case, the (1-1)th active layer ACT1-1 and the (1-2)th active layer ACT1-2 may form different transistor structures or a partial structure of the pixel circuit.

A plane defined in the present disclosure is a direction extending in a first direction DR1 and a second direction DR2, and may be defined with respect to a plane on which the base layer BSL is disposed. Furthermore, the third direction DR3 may be defined with respect to a thickness direction of the base layer BSL. The third direction DR3 may be a light emission direction of the display device DD.

The first interlayer conductive layer ICL1 may be interposed between the first interlayer insulating layer ILD1 and the second interlayer insulating layer ILD2. In this case, the first interlayer conductive layer ICL1 may be covered by the second interlayer insulating layer ILD2. The first interlayer conductive layer ICL1 may be disposed in the display area DA. The first interlayer conductive layer ICL1 may form at least a portion of a circuit element (e.g., a gate electrode portion of a transistor or the like) included in the pixel circuit configured to drive light emitting elements LD.

The first interlayer conductive layer ICL1 may be electrically connected to the second upper conductive layer UCL2 through the second contact member CNP2 penetrating the second to fifth interlayer insulating layers ILD2 to ILD5. The second contact member CNP2 may be formed with the second upper conductive layer UCL2 through the same process, and include the same material as the second upper conductive layer UCL2. The second contact member CNP2 may be a structure electrically connecting the first interlayer conductive layer ICL1 to a conductive layer (e.g., the second upper conductive layer UCL2) of the third layer L3.

In some embodiments, the first interlayer conductive layer ICL1 may include a (1-1)th interlayer conductive layer ICL1-1 and a (1-2)th interlayer conductive layer ICL1-2. The (1-1)th interlayer conductive layer ICL1-1 and the (1-2)th interlayer conductive layer ICL1-2 may be spaced apart from each other, but may be formed through the same fabrication process. The (1-1)th interlayer conductive layer ICL1-1 and the (1-2)th interlayer conductive layer ICL1-2 may form different transistor structures or a partial structure of the pixel circuit.

Meanwhile, in some embodiments, the first contact member CNP1 and the second contact member CNP2 may be electrically connected respectively to targets formed in different layers (or at different heights), and be fabricated (e.g., formed) through the same process. Accordingly, fabrication processes of the display device DD may be simplified, and process cost may be reduced as well. The fabrication processes will be described in detail later.

The second interlayer conductive layer ICL2 may be interposed between the second interlayer insulating layer ILD2 and the third interlayer insulating layer ILD3. In this case, the second interlayer conductive layer ICL2 may be covered by the third interlayer insulating layer ILD3. The second interlayer conductive layer ICL2 may be disposed in the display area DA. The second interlayer conductive layer ICL2 may form at least a portion (e.g., a connection portion between circuit elements) of a circuit element included in the pixel circuit configured to drive the light emitting element LD.

The second interlayer conductive layer ICL2 may be electrically connected to the second upper conductive layer UCL2 through the second contact member CNP2 penetrating the third to fifth interlayer insulating layers ILD3 to ILD5. The second contact member CNP2 may be formed with the second upper conductive layer UCL2 through the same process, and include the same material as the second upper conductive layer UCL2. The second contact member CNP2 may be a structure electrically connecting the second interlayer conductive layer ICL2 to a conductive layer (e.g., the second upper conductive layer UCL2) of the third layer L3.

The second interlayer conductive layer ICL2 may include a (2-1)th interlayer conductive layer ICL2-1 and a (2-2)th interlayer conductive layer ICL2-2. The (2-1)th interlayer conductive layer ICL2-1 and the (2-2)th interlayer conductive layer ICL2-2 may be spaced apart from each other, but may be formed through the same process The (2-1)th interlayer conductive layer ICL2-1 and the (2-2)th interlayer conductive layer ICL2-2 may form different transistor structures or a partial structure of the pixel circuit. For example, the (2-1)th interlayer conductive layer ICL2-1 adjacent to the first active layer ACT1 may overlap the first active layer ACT1 in the third direction DR3. The (2-2)th interlayer conductive layer ICL2-2 adjacent to the second active layer ACT2 may overlap the second active layer ACT2 in the third direction DR3. In this case, the (2-2)th interlayer conductive layer ICL2-2 may be electrically connected to the second upper conductive layer UCL2 through the second contact member CNP2 penetrating the third to fifth interlayer insulating layers ILD3 to ILD5, but the (2-1)th interlayer conductive layer ICL2-1 may not be electrically connected to the second upper conductive layer UCL2.

The second active layer ACT2 may be interposed between the third interlayer insulating layer ILD3 and the fourth interlayer insulting layer ILD4. In this case, the second active layer ACT2 may be covered by the fourth interlayer insulating layer ILD4. The second active layer ACT2 may be disposed in the display area DA. The second active layer ACT2 may form at least a portion of a circuit element (e.g., a semiconductor portion of the driving transistor, the switching transistor, or the like) included in the pixel circuit configured to drive the light emitting element LD.

In some embodiments, the second active layer ACT2 may include an oxide semiconductor. The second active layer ACT2 may include Indium Gallium Zinc Oxide (IGZO).

The second active layer ACT2 may be electrically connected to the third upper conductive layer UCL3 through the third contact member CNP3 penetrating the fourth and fifth interlayer insulating layers ILD4 and ILD5. The third contact member CNP3 may be formed with the third upper conductive layer UCL3 through the same process, and include the same material as the third upper conductive layer UCL3. The third contact member CNP3 may be a structure electrically connecting the second active layer ACT2 to a conductive layer (e.g., the third upper conductive layer UCL3) of the third layer L3.

The third interlayer conductive layer ICL3 may be interposed between the fourth interlayer insulating layer ILD4 and the fifth interlayer insulting layer ILD5. In this case, the third interlayer conductive layer ICL3 may be covered by the fifth interlayer insulating layer ILD5. The third interlayer conductive layer ICL3 may form at least a portion (e.g., a connection portion between circuit elements) of a circuit element included in the pixel circuit configured to drive the light emitting element LD.

In accordance with an embodiment, a risk that a conductive connection structure formed by the contact member CNP can be damaged may be sensed. Accordingly, the reliability of an electrical signal defined in the pixel circuit layer PCL may be improved.

For example, as depicted in FIG. 4, the contact member CNP may penetrate at least some (e.g., the first to third interlayer insulating layers ILD1 to ILD3) of the interlayer insulating layers ILD and may be adjacent (e.g., directly adjacent) to a side surface SID formed by the interlayer insulating layers ILD.

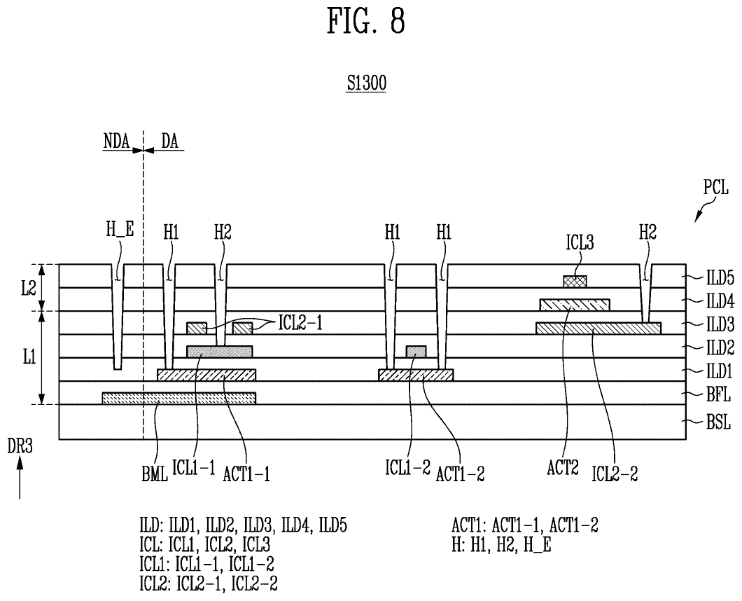

In some embodiments, the side surface SID may form a continuous surface. As described above, the interlayer insulating layers ILD directly adjacent to each other may include different materials. Experimentally, when an etching process for forming a contact hole H (see FIG. 8) in the interlayer insulating layers ILD to manufacture the contact member CNP, amounts with which the interlayer insulating layers ILD are etched may be different from each other when a difference in etch rate between the interlayer insulating layers ILD is largely defined. However, in accordance with an embodiment, the etching process may be performed under an environment in which etch rates of the interlayer insulating layers ILD are roughly uniform, and accordingly, the side surface SID may form a roughly continuous surface. This will be described in detail later.

FIG. 4 is a schematic enlarged view of area EA1 shown in FIG. 3 and may illustrate a cross-sectional structure of the first contact member CP1, but a structural characteristic shown in FIG. 4 may be applied to each of the first to third contact members CNP1 to CNP3 and the edge contact member CNP_E.

The first to third upper conductive layers UCL1 to UCL3 and the edge upper conductive layer UCL_E may be disposed on the fifth interlayer insulating layer ILD5, and may be covered by the via layer VIA. The first to third upper conductive layers UCL1 to UCL3 may be disposed in the display area DA, and the edge upper conductive layer UCL_E may be disposed in the non-display area NDA.

In some embodiments, the first upper conductive layer UCL1 may form a source electrode and/or a drain electrode of a transistor which the first active layer ACT1 forms. The second upper conductive layer UCL2 may form at least a partial conductive connection structure of a circuit element which each of the first active layer ACT1 and the second active layer ACT2 forms. The third upper conductive layer UCL3 may form a source electrode and/or a drain electrode of a transistor which the second active layer ACT2 forms.

A plurality of light emitting elements LD of the light emitting element layer LEL may be disposed on an area of the pixel circuit layer PCL. For example, the light emitting elements LD may be disposed in the display area DA, but may not be disposed in the non-display area NDA. In some embodiments, the light emitting elements LD may be electrically connected to the pixel circuit formed in the pixel circuit layer PCL. For example, the light emitting elements LD may be electrically connected to at least a portion of the upper conductive layer UCL. The pixel circuit may be formed by at least a portion of each of one or more of the lower auxiliary conductive layer BML, the first active layer ACT1, the first to third interlayer conductive layers ICL1 to ICL3, the second active layer ACT2, and the upper conductive layer UCL.

In some embodiments, the display device DD may further include various layers disposed on the light emitting element layer LEL. For example, although not shown herein, the display device DD may further include a window layer.

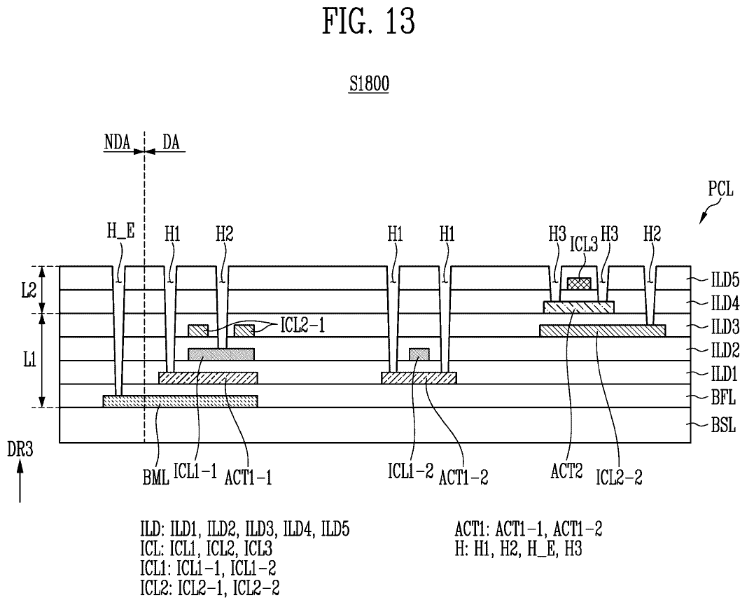

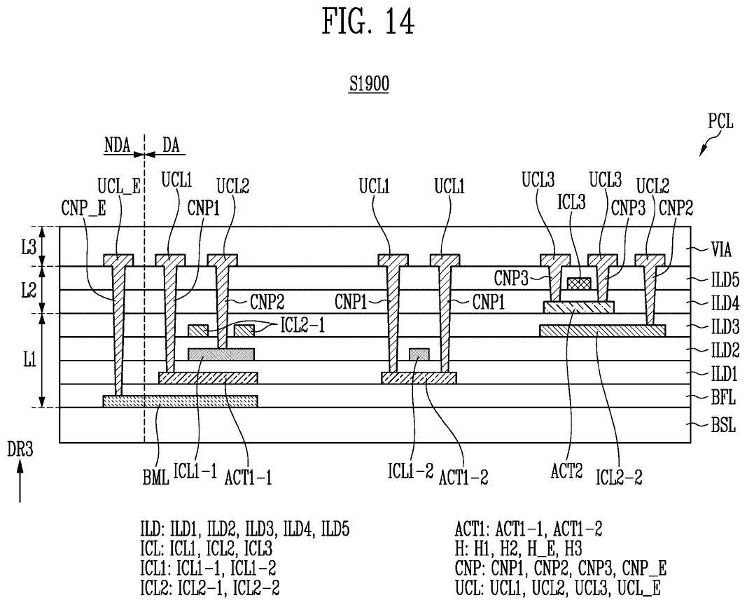

Next, a method of manufacturing (i.e., fabrication process) the display device DD in accordance with an embodiment of the present disclosure will be described with reference to FIGS. 5 to 15. In FIGS. 5 to 15, descriptions of portions overlapping those described above will be simplified or will not be repeated.

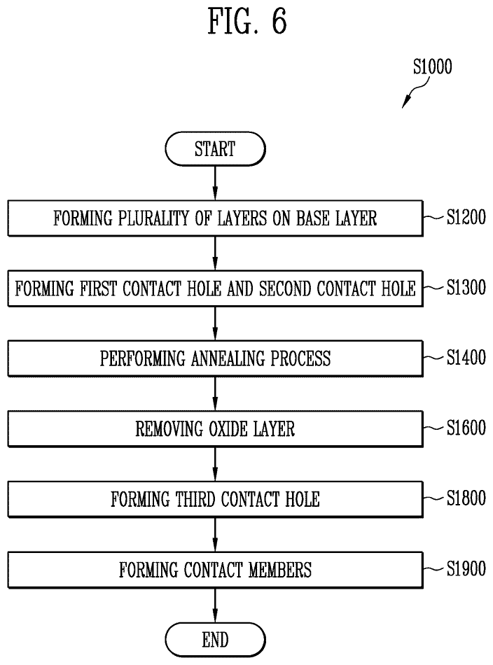

FIG. 5 is a schematic flowchart illustrating a method of manufacturing the display device in accordance with an embodiment of the present disclosure. FIG. 6 is a schematic flowchart illustrating a step of manufacturing a pixel circuit layer in accordance with an embodiment of the present disclosure.

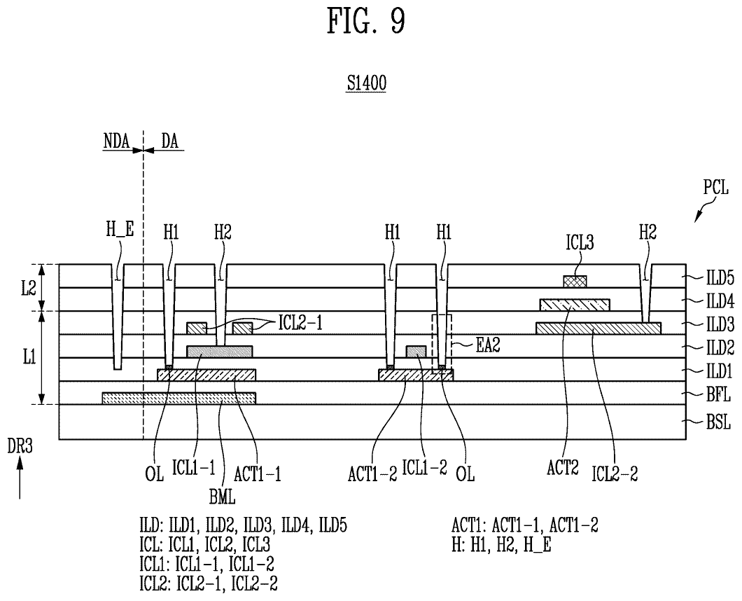

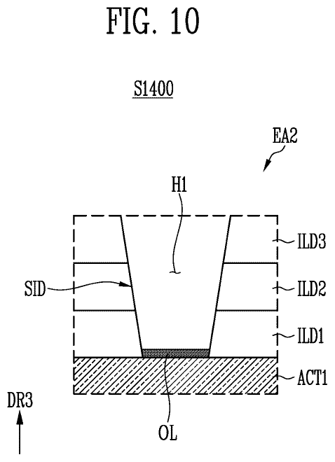

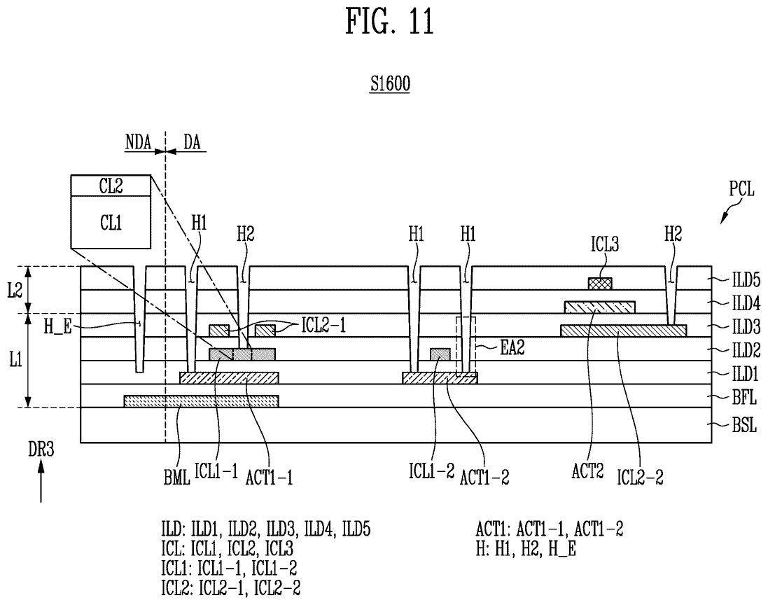

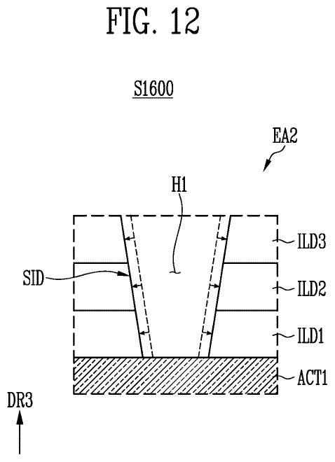

FIGS. 7 to 15 are schematic sectional views illustrating a method of manufacturing the display device in accordance with an embodiment of the present disclosure. FIG. 10 is a schematic enlarged view of area EA2 shown in FIG. 9. FIG. 12 is a schematic enlarged view of area EA2 shown in FIG. 11. FIGS. 9 and 11 may schematically illustrate sectional structures of areas corresponding to each other in different processes.

Referring to FIG. 5, the method of manufacturing the display device DD in accordance with the embodiment of the present disclosure may include a step of manufacturing a pixel circuit layer S1000 and a step of manufacturing a light emitting element layer S2000.

Referring to FIG. 6, the step of manufacturing the pixel circuit layer S1000 may include forming a plurality of layers on a base layer S1200, forming a first contact hole and a second contact hole S1300, performing an annealing process S1400, removing an oxide layer S1600, forming a third contact hole S1800, and forming a plurality of contact members S1900.

Referring to FIGS. 5 to 7, during the step of forming the plurality of layers on the base layer S1200, a plurality of insulating layers and conductive layers for fabricating a pixel circuit layer PCL may be formed (e.g., deposited) on a base layer BSL.

In some embodiments, the conductive layers or the insulating layers on the base layer BSL may be formed through an ordinary manufacturing process for a semiconductor device. For example, the conductive layers or the insulating layers on the base layer BSL may be formed through a photolithography process including various etching techniques (wet etching, dry etching, and the like) and various deposit techniques (sputtering, chemical vapor deposition, and the like). However, the present disclosure is not necessarily limited to a specific example.

During this step S1200, first and second layers L1 and L2 may be formed on the base layer BSL. For example, a lower auxiliary conductive layer BML, a first active layer ACT1, a first interlayer conductive layer ICL1, a second interlayer conductive layer ICL2, a second active layer ACT2, and a third interlayer conductive layer ICL3 may be patterned on the base layer BSL, and a buffer layer BFL and first to fifth interlayer insulating layers ILD1 to ILD5 may be formed between the above layers.

During this step S1200, each of the first interlayer conductive layer ICL1 and the second interlayer conductive layer ICL2 may include a first conductive layer CL1 and the second conductive layer CL2. In this case the second conductive layer CL2 may be disposed on the first conductive layer CL1. As described above, the first conductive layer CL1 may include aluminum (Al), and the second conductive layer CL2 may include titanium (Ti). The first active layer ACT1 may be fabricated by patterning a material for forming at least one of Low-Temperature Polycrystalline Silicon (LTPS), Hybrid Oxide Polycrystalline silicon (HOP), and Hybrid Oxide Low-Temperature Polycrystalline silicon (HOL), and the second active layer ACT2 may be fabricated by patterning a material for forming an oxide semiconductor layer.

Referring to FIGS. 5, 6, and 8, during the step S1300 of forming the first contact hole and the second contact hole, a contact hole H may be formed, which penetrate at least a portion of the interlayer insulating layers ILD.

During this step S1300, at least a portion of the interlayer insulating layers ILD may be etched (e.g., dry-etched), and the contact hole H may be fabricated. The contact hole H may include a first contact hole H1 for a first contact member CNP1 and a second contact hole H2 for a second contact member CNP2. In some embodiments, the contact hole H may further include an edge contact hole H_E for an edge contact member CNP_E. In this case, the first contact hole H1 may penetrate through first to fifth interlayer insulating layers ILD1 to ILD5. One of the second contact holes H2 may penetrate through second to fifth interlayer insulating layers ILD2 to ILD5, and the other second contact hole H2 may penetrate through third to fifth interlayer insulating layers ILD3 to ILD5. The edge contact hole H_E may penetrate through first to fifth interlayer insulating layers ILD1 to ILD5.

During this step S1300, the first contact hole H1 may expose the first active layer ACT1. One of the second contact holes H2 may expose the first interlayer conductive layer ICL1, and the other second contact hole H2 may expose the second interlayer conductive layer ICL2. The edge contact hole H_E may expose a portion of the first interlayer insulating layer ILD1.

In accordance with an embodiment, the first contact hole H1 and the second contact hole H2 may be formed through the same process. For example, the first contact hole H1 and the second contact hole H2 may be dry-etched through the same etch mask, and a strip process may be integrally performed during a process of fabricating the first contact hole H1 and the second contact hole H2. Accordingly, the overall process of the first contact hole H1 and the second contact hole H2 may be simplified, and thus process time and convenience may be improved.

Meanwhile, targets respectively exposed by the first contact hole H1 and the second contact hole H2 are different from each other as described above. When the first contact hole H1 and the second contact hole H2 were conventionally formed simultaneously, a risk that some layers would be damaged existed. However, in accordance with the present disclosure, process characteristics are improved by reducing the fabrication process so that the above-described risk may be reduced.

Referring to FIGS. 5, 6, 9, and 10, during the step of performing the annealing process S1400, an annealing process may be performed, which is used to improve an ion implantation characteristic of the exposed first active layer ACT1 and to prevent damage of the first active layer ACT1.

During this step S1400, the annealing process may be accomplished through various techniques. For example, in the annealing process, a high-temperature heating technique using a furnace, Rapid Thermal Annealing (RTA) as a rapid annealing technique, or the like may be used. However, the present disclosure is not limited to a specific example.

During this step S1400, an oxide layer OL may be formed on the exposed first active layer ACT1. For example, since the annealing process may be performed by a roughly large temperature change, the property of a surface of the exposed first active layer ACT1 may be changed compared to before the annealing process. The first active layer ACT1 may include at least one of Low-Temperature Polycrystalline Silicon (LTPS), Hybrid Oxide Polycrystalline silicon (HOP), and Hybrid Oxide Low-Temperature Polycrystalline silicon (HOL), and therefore, the oxide layer OL including silicon oxide may be formed on a top surface of the exposed first active layer ACT1.

During this step S1400, since the exposed first and second interlayer conductive layers ICL1 and ICL2 may not include any poly-silicon material, a layer similar to the oxide layer OL may not be formed on the exposed first and second interlayer conductive layers ICL1 and ICL2.

Referring to FIGS. 5, 6, 11, and 12, during the step of removing the oxide layer S1600, the oxide layer OL may be removed, and accordingly, the first active layer ACT1 may be re-exposed.

This step of removing the oxide layer S1600 may be referred as a cleaning process.

During this step S1600, the oxide layer OL may be removed through a cleaning process through hydrogen fluoride (HF). Chemical reactions associated during the cleaning process using HF are as follows.

HF+NH₃→NH₄F 1. Etchant preparation step

6NH₄F+SiO₂→(NH₄)₂SiF₆(s)+2H₂O(g)+4NH₃(g) 2. Oxide etching step

(NH₄)₂SiF₆(s)→2NH₃(g)+SiF₄(g)+2HF(g). 3. Ramping step

Firstly, an etchant including NH₄F may be prepared through HF and NH₃ gases. In addition, (NH₄)₂SiF₆ (s) may be reduced as the prepared NH₄F reacts with SiO₂ included in the oxide layer OL. The (NH₄)₂SiF₆(s) may be decomposed into NH₃(g), SiF₄(g), and HF (g) to be removed under a relatively high temperature environment in the ramping step. Accordingly, the oxide layer OL formed on the first active layer ACT1 may be removed.

Experimentally, when the oxide layer OL is removed through a Buffered Oxide Etchant (BOE), the exposed first and second interlayer conductive layers ICL1 and ICL2 may be damaged by the BOE. For example, the BOE may etch the first and second conductive layers CL1 and CL2 of each of the first and second interlayer conductive layers ICL1 and ICL2. A risk that resistances of the first and second interlayer conductive layers ICL1 and ICL2 will be increased may occur, and the reliability of an electrical signal provided to the pixel circuit layer PCL may be damaged or failed.

However, in accordance with the embodiment of the present disclosure, when the above-described process is performed, the damage of the first and second interlayer conductive layers ICL1 and ICL2 may not substantially occur. For example, reactivity of the etchant including NH₄F with a conductive material (e.g., titanium (Ti)) forming a top surface of each of the first and second interlayer conductive layers ICL1 and ICL2 may not substantially exist. Accordingly, during the process of removing the oxide layer OL, the conductive structure of the first and second interlayer conductive layers ICL1 and ICL2 may be substantially maintained even when the etchant including NH₄F is directly exposed to the top surface (e.g., the second conductive layer CL2) of each of the first and second interlayer conductive layers ICL1 and ICL2. Accordingly, the above-described risk may be reduced.

Moreover, when the process of removing the oxide layer OL is performed through the conventional BOE, it was difficult for a structure corresponding to the first contact hole H1 and the second contact hole H2 to be fabricated through the same process due to a risk that damage of the conductive structure will occur. However, in the embodiment of the present disclosure, the process of removing the oxide layer OL may be performed using an etchant of which reactivity with the first and second interlayer conductive layers ICL1 and ICL2 may not be substantially large, and therefore, the first and second contact holes H1 and H2 may be etched through the same process without affecting each other. Accordingly, the number of masks for performing the etching process may decrease so that fabrication processes may be simplified.

Meanwhile, as depicted in FIG. 12, due to the etchant used during removing the oxide layer S1600, at least a portion of the interlayer insulating layers ILD (e.g., at least a portion of the first to third interlayer insulating layers ILD1 to ILD3) may be removed. In accordance with an embodiment, etch rates with respect to the etchant including NH₄F may be roughly uniform in all the interlayer insulating layers ILD. For example, an etch selectivity of silicon oxide (SiOₓ) to Silicon nitride (SiNₓ) with respect to the etchant including NH₄F may be around 0.9:1 to 1.5:1. Accordingly, a side surface SID of the interlayer insulating layers ILD toward the contact hole H may form a roughly continuous surface.

Referring to FIGS. 5, 6, and 13, during the step of forming the third contact hole S1800, a third contact hole H3 may be formed, which penetrates at least a portion of the interlayer insulating layers ILD. For example, the third contact hole H3 may penetrate the fourth and fifth interlayer insulating layers ILD4 and ILD5.

During this step S1800, at least a portion of the interlayer insulating layers ILD may be etched, and the third contact hole H3 may be fabricated. The third contact hole H3 may be used to form a third contact member CNP3 and may be exposed to the second active layer ACT2 disposed on the third interlayer insulting layer ILD3.

During this step S1800, the edge contact hole H_E may further penetrate the buffer layer BFL and the first interlayer insulating layer ILD1 so that the edge contact hole H_E may be exposed to the lower auxiliary conductive layer BML.

In some embodiments, the second active layer ACT2 may not include a poly-silicon-based material, but may include an oxide semiconductor material. Therefore, any additional annealing process may not be needed.

Referring to FIGS. 5, 6, and 14, during the step of forming the contact members S1900, a plurality of upper conductive layers UCL may be patterned, and a plurality of contact members CNP may be formed.

During this step S1900, when conductive layers for forming the upper conductive layers UCL are formed (e.g., deposited), a conductive material may be provided to the contact holes H so that the contact members CNP may be fabricated. For example, the first contact member CNP1 electrically connected to the first upper conductive layer UCL1 and the first active layer ACT1 may be fabricated in the first contact hole H1. The second contact member CNP2 electrically connected to the second upper conductive layer UCL2 and the first interlayer conductive layer ICL1 and the second interlayer conductive layers ICL2 may be fabricated in the second contact hole H2. The third contact member CNP3 electrically connected to a third upper conductive layer UCL3 and the second active layer ACT2 may be fabricated in the third contact hole H3. The edge contact member CNP_E electrically connected to the edge upper conductive layer UCL_E and the lower auxiliary conductive layer BML may be fabricated in the edge contact hole H_E.

During this step S1900, after the upper conductive layer UCL is patterned, a via layer VIA may be formed. The via layer VIA may be a planarization layer so that the via layer VIA may correct a step difference formed by the upper conductive layer UCL.

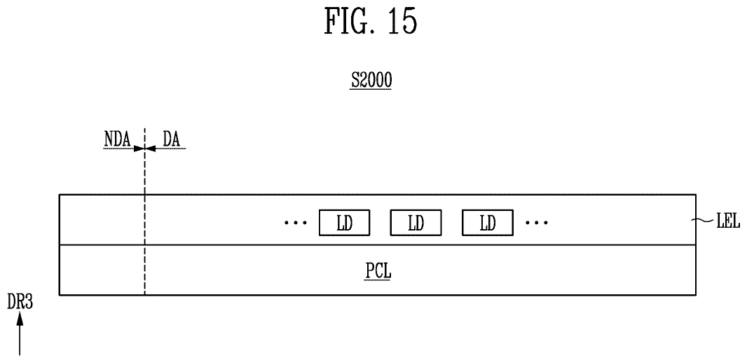

Referring to FIGS. 5 and 15, during step of manufacturing a light emitting element layer S2000, a plurality of light emitting elements LD, a conductive structure electrically connected to the plurality of light emitting elements LD, an insulating layer, and the like may be formed on the pixel circuit layer PCL.

During this step S2000, the plurality of light emitting elements LD may be disposed on the pixel circuit layer PCL (e.g., the via layer VIA) through various manners, and a process of disposing the plurality of light emitting elements LD is not limited to a specific example. In some embodiments, at least a portion of a conductive structure formed in the light emitting element layer LEL may be electrically connected to at least a portion of the upper conductive layers UCL through the via layer VIA. Accordingly, the pixel circuit is electrically connected to the plurality of light emitting elements LD, to emit light.

In accordance with the present disclosure, there can be provided a display device and a method of manufacturing a display device, in which fabrication processes can be simplified.

In accordance with the present disclosure, provided is a display device and a method of manufacturing a display device, in which a risk that a conductive structure included in the display device will be damaged can be reduced.

In accordance with the present disclosure, provided is a display device and a method of manufacturing a display device, in which a risk that a portion of a contact structure included in the display device will be disconnected can be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a pixel circuit layer including a base layer, a first layer which is disposed on the base layer and includes a first active layer, a second layer which is disposed on the first layer and includes a second active layer, and a third layer which is disposed on the second layer and includes an upper conductive layer; and
a light emitting element layer disposed on the pixel circuit layer, the light emitting element layer including a plurality of light emitting elements,
wherein the first active layer and the second active layer include different semiconductor materials,
wherein each of the first layer and the second layer includes an interlayer insulating layer and an interlayer conductive layer,
wherein the upper conductive layer includes a first upper conductive layer, a second upper conductive layer, and a third upper conductive layer,
wherein the first active layer of the first layer is electrically connected to the first upper conductive layer through a first contact member penetrating the first and second layers,
wherein the interlayer conductive layer of the first layer is electrically connected to the second upper conductive layer through a second contact member penetrating the first and second layers,
wherein the second active layer of the second layer is electrically connected to the third upper conductive layer through a third contact member penetrating the second layer, and
wherein the interlayer insulating layer of the first layer forms continuous side surfaces around the first contact member, the second contact member, and the third contact member.

2. The display device of claim 1, wherein the first active layer includes at least one of Low-Temperature Polycrystalline Silicon (LTPS), Hybrid Oxide Polycrystalline silicon (HOP), and Hybrid Oxide Low-Temperature Polycrystalline silicon (HOL).

3. The display device of claim 1, wherein the second active layer includes Indium Gallium Zinc Oxide (IGZO).

4. The display device of claim 1, wherein the interlayer conductive layer of the first layer includes a first conductive layer including aluminum (Al) and a second conductive layer which is disposed on the first conductive layer and includes titanium (Ti).

5. The display device of claim 1, wherein the interlayer conductive layer of the first layer includes a first interlayer conductive layer and a second interlayer conductive layer spaced apart from the first interlayer conductive layer,
wherein the first interlayer conductive layer is disposed on a different layer from the second interlayer conductive layer, and
wherein the second interlayer conductive layer overlaps the second active layer along a thickness direction.

6. The display device of claim 5, further comprising:
a display area and a non-display area;
a lower auxiliary conductive layer on the base layer;
a via layer disposed on the interlayer insulating layer, and
wherein a portion of the lower auxiliary conductive layer overlaps the first active layer in a thickness direction, and
wherein a portion of the lower auxiliary conductive layer is disposed in the display area, and another portion of the lower auxiliary conductive layer is disposed in the non-display area.

7. The display device of claim 1, wherein the interlayer insulating layer includes first, second, third, fourth, and fifth interlayer insulating layers, and
wherein layers directly adjacent to each other among the first, second, third, fourth, and fifth interlayer insulating layers include different materials.

8. The display device of claim 7, wherein the different materials include silicon oxide (SiOₓ) and silicon nitride (SiNₓ).

9. A method of manufacturing a display device, the method comprising:
fabricating a pixel circuit layer; and
fabricating a light emitting element layer on the pixel circuit layer,
wherein the fabricating of the pixel circuit layer includes:
forming, on a base layer, a plurality of layers including a first active layer, interlayer insulating layers, and an interlayer conductive layer;
forming a first contact hole and a second contact hole, wherein the first contact hole is exposed to the first active layer, and the second contact hole is exposed to the interlayer conductive layer;
performing an annealing process, wherein the performing of the annealing process includes forming an oxide layer on the first active layer; and
removing the oxide layer.

10. The method of claim 9, wherein the removing of the oxide layer is accomplished by performing a cleaning process using Hydrogen Fluoride (HF).

11. The method of claim 10, wherein the performing of the cleaning process is accomplished by causing chemical reactions including an etchant preparation process, an oxide etching process, and a ramping process as follows:
HF+NH₃→NH₄F [Etchant preparation process]
6NH₄F+SiO₂→(NH₄)₂SiF₆(s)+2H₂O (g)+4NH₃(g) [Oxide etching process]
(NH₄)₂SiF₆(s)→2NH₃(g)+SiF₄(g)+2HF(g). [Ramping process]

12. The method of claim 10, wherein the interlayer insulating layers include first, second, third, fourth, and fifth interlayer insulating layers directly adjacent to each other,
wherein each of the first, second, third, fourth, and fifth interlayer insulating layers directly adjacent to each other includes silicon oxide (SiOₓ) and silicon nitride (SiNₓ₎, and
wherein an etch selectivity of silicon oxide (SiOₓ) to silicon nitride (SiNₓ) with respect to an etchant provided in the cleaning process is 0.9:1 to 1.5:1.

13. The method of claim 9, wherein the first active layer includes at least one of Low-Temperature Polycrystalline Silicon (LTPS), Hybrid Oxide Polycrystalline silicon (HOP), and Hybrid Oxide Low-Temperature Polycrystalline silicon (HOL), and
wherein the oxide layer includes silicon oxide (SiOₓ).

14. The method of claim 10, wherein the interlayer conductive layer includes a first conductive layer a second layer disposed on the first conductive layer,
wherein the first conductive layer includes aluminum (Al), and the second conductive layer includes titanium (Ti), and
wherein the performing of the annealing process is accomplished by a high-temperature heating technique using a furnace or Rapid Thermal Annealing (RTA) as a rapid annealing technique.

15. The method of claim 9, further comprising forming a third contact hole exposed to the second active layer,
wherein the plurality of layers further includes a second active layer including a semiconductor material different from a semiconductor material of the first active layer.

16. The method of claim 15, wherein the second active layer includes IGZO, and
wherein, after the forming of the third contact hole, no additional annealing process is performed.

17. The method of claim 15, further comprising forming a plurality of contact members,
wherein the forming of the plurality of contact members is accomplished by patterning a plurality of upper conductive layers,
wherein the upper conductive layer includes a first upper conductive layer, a second upper conductive layer, a third upper conductive layer, and an edge upper conductive layer, and
wherein the patterning of the upper conductive layer includes:
forming a first contact member electrically connecting the first upper conductive layer to the first active layer;
forming a second contact member electrically connecting the second upper conductive layer to the interlayer conductive layer;
forming a third contact member electrically connecting the third upper conductive layer to the second active layer; and
forming an edge contact member electrically connecting the edge upper conductive layer to a lower auxiliary conductive layer.

18. The method of claim 9, wherein the first contact hole and the second contact hole are formed through an etching process using a same etch mask.

19. The display device of claim 1, wherein the first upper conductive layer, the second upper conductive layer, and the third upper conductive layer are disposed in a display area, and the edge upper conductive layer is disposed in a non-display area.

20. A method of manufacturing a pixel circuit layer, the method comprising:
forming a plurality of layers on a base layer, wherein the plurality of layer includes a first active layer, a second active layer, an interlayer insulating layer, and an interlayer conductive layer;
forming a first contact hole and a second contact hole, wherein the first contact hole is exposed to the first active layer, and the second contact hole is exposed to the interlayer conductive layer;
performing an annealing process, wherein the performing of the annealing process includes forming an oxide layer on the first active layer;
removing the oxide layer, wherein the removing of the oxide layer is accomplished by performing a cleaning process using Hydrogen Fluoride (HF),
forming a third contact hole, wherein the third contact hole is exposed to the second active layer, and
forming a plurality of contact members including a first contact member, a second contact member, and a third contact member, wherein the forming of the plurality of contact members is accomplished by patterning a plurality of upper conductive layers,
wherein the upper conductive layer includes a first upper conductive layer, a second upper conductive layer, and a third upper conductive layer, and
wherein the first active layer is electrically connected to the first upper conductive layer through the first contact member,
wherein the interlayer conductive layer is electrically connected to the second upper conductive layer through the second contact member,
wherein the second active layer is electrically connected to the third upper conductive layer through the third contact member, and
wherein the interlayer insulating layer forms continuous side surfaces around the first contact member, the second contact member, and the third contact member.
